(19) United States
(12) Patent Application Publication
(10) Pub. No.: US 2019/0157343 A1
(43) Pub. Date: May 23, 2019

(54) MAGNETIZATION ROTATIONAL ELEMENT, MAGNETORESISTANCE EFFECT ELEMENT, INTEGRATED DEVICE, AND METHOD OF MANUFACTURING INTEGRATED DEVICE

(71) Applicant: TDK CORPORATION, Tokyo (JP)

(72) Inventors: Tomoyuki SASAKI, Tokyo (JP); Yohei SHIOKAWA, Tokyo (JP)

(73) Assignee: TDK CORPORATION, Tokyo (JP)

(21) Appl. No.: 15/780,080

(22) PCT Filed: Sep. 13, 2017
(86) PCT No.: PCT/JP2017/033030

§ 371 Date: May 30, 2018

(30) Foreign Application Priority Data
Dec. 2, 2016 (JP) 2016-235238

(51) Int. Cl. H01L 27/22; H01L 43/02; H01L 43/10; H01L 43/12

(52) U.S. Cl. CPC H01L 27/222; H01L 43/12; H01L 43/10; H01L 43/02

(57) ABSTRACT

A magnetization rotational element includes a single crystalline substrate, a magnetization stabilizing layer, a first ferromagnetic metal layer, and a joint layer in that order and at least the single crystalline substrate, the magnetization stabilizing layer, and the first ferromagnetic metal layer are single-crystallized.

### TECHNICAL FIELD

The present disclosure relates to a magnetization rotational element, a magnetoresistance effect element, an integrated device, and a method of manufacturing an integrated device.

Priority is claimed on Japanese Patent Application No. 2016-235238, filed Dec. 2, 2016, the content of which is incorporated herein by reference.

### BACKGROUND ART

Giant magnetoresistance (GMR) elements constituted of a multilayer film including a ferromagnetic layer and a nonmagnetic layer and tunneling magnetoresistance (TMR) elements using an insulating layer (tunnel barrier layer or barrier layer) as a nonmagnetic layer are known as magnetoresistance effect elements. These elements can be used for magnetic sensors, high-frequency components, magnetic heads, and nonvolatile random access memories (magnetoresistance random access memory (MRAM)) and have attracted attention.

A plurality of elements have been attempted to be integrated into a single element to achieve a specific complicated function. An integrated circuit (IC) is an example and Patent Literature 1 describes an integrated circuit obtained by laminating a plurality of devices in a three-dimensional manner.

Conventionally, magnetoresistance effect elements represented by TMR elements or GMR elements are used for applications such as magnetic heads in many cases and integration effects have not been sufficiently obtained. However, there is increased demand for the development of an application thereof as memory cells such as MRAMs and incorporation of magnetoresistance effect elements into integrated circuits.

However, magnetoresistance effect elements are elements in which layers corresponding to several atomic layers are laminated. For this reason, in order to incorporate magnetoresistance effect elements into integrated circuits as compared with capacitors, diodes, and the like incorporated into conventional integrated circuits, more precise control is required.

For example, Non-Patent Literature 1 states that a high magnetic anisotropy is not obtained even when a spin injection memory (spin torque transfer magnetic random access memory (STT-MRAM)) is laminated above an integrated substrate containing a semiconductor element.

Non-Patent Literature 1 states that the integrated substrate containing the semiconductor element does not have crystal orientation as a reason why a high magnetic anisotropy cannot be realized even when the STT-MRAM is laminated above the integrated substrate. Non-Patent Literature 1 states that an integrated substrate having no crystal orientation is not desirable as an underlying layer on which an epitaxial layer is laminated and a magnetization film having a high magnetic anisotropy cannot be laminated above the integrated substrate.

### CITATION LIST

### Patent Literature

[Patent Literature 1]

Japanese Unexamined Patent Application, First Publication No. 2008-288384
[Non-Patent Literature 1]

K. Yakushiji, A. Sugihara, H. Takagi, Y. Kurashima, N. Watanabe, K. Kikuchi, M. Aoyagi, and S. Yuasa, Overview of the 40th Annual Conference on MAGNETICS in Japan, 6aA-7 (2016).

### SUMMARY OF INVENTION

### Technical Problem

In Non-Patent Literature 1, an amorphous Ta layer is laminated between an Si substrate and a magnetoresistance effect element. In other words, there is no crystallographic connection between the Si substrate and the magnetoresistance effect element. For this reason, the magnetic anisotropy due to which the magnetoresistance effect element (magnetic tunnel junction (MTJ)) described in Non-Patent Literature 1 is obtained is substantially the same as that in a case in which a magnetoresistance effect element is laminated above an integrated substrate on which an amorphous layer is laminated.

The present disclosure was made in view of the above-described circumstances and an object of the present disclosure is to provide a magnetization rotational element, a magnetoresistance effect element, and an integrated device which have a high magnetic anisotropy even above an integrated substrate and a method of manufacturing the same.

### Solution to Problem

The inventors of the present invention carried out intensive research, and as a result, found that a high magnetic anisotropy can be realized when a magnetization rotational element or a magnetoresistance effect element joined to an integrated substrate is epitaxially grown above a single crystal.

(1) A magnetization rotational element according to a first aspect includes: a single crystalline substrate; a magnetization stabilizing layer; a first ferromagnetic metal layer; and a joint layer in an order, wherein at least the single crystalline substrate, the magnetization stabilizing layer, and the first ferromagnetic metal layer are single-crystallized as a whole.

(2) In the magnetization rotational element according to the above aspect, the single crystalline substrate and the magnetization stabilizing layer may contain different materials.

(3) In the magnetization rotational element according to the above aspect, the single crystalline substrate may be made of at least one selected from a group consisting of Si, GaAs, Ge, MgO, a material with a spinel type structure, and a material with a cubic perovskite structure.

(4) In the magnetization rotational element according to the above aspect, the magnetization stabilizing layer may be made of at least one selected from a group consisting of MgO, Ir, and a material with a spinel type structure.

(5) In the magnetization rotational element according to the above aspect, the first ferromagnetic metal layer may be made of a cubic ferromagnetic metal containing Fe.

(6) In the magnetization rotational element according to the above aspect, a degree of lattice matching between the single crystalline substrate and the magnetization stabilizing layer may be 10% or less.

(7) In the magnetization rotational element according to the above aspect, a degree of lattice matching between the magnetization stabilizing layer and the first ferromagnetic metal layer may be 6% or less.

(8) In the magnetization rotational element according to the above aspect, a thickness of the magnetization stabilizing layer may be 1 nm or more.

(9) In the magnetization rotational element according to the above aspect, the joint layer may contain at least one element selected from a group consisting of Ta, Au, In, Cu, Ag, Pt, Pd, Ti, V, and Ru.

(10) A magnetoresistance effect element according to a second aspect includes: between the first ferromagnetic metal layer and the joint layer of the magnetization rotational element according to the above aspect, a nonmagnetic layer and a second ferromagnetic metal layer in an order from the first ferromagnetic metal layer side.

(11) In the magnetoresistance effect element according to the above aspect, the second ferromagnetic metal layer may have a synthetic anti-ferromagnetic structure.

(12) An integrated device according to a third aspect includes: an integrated substrate containing a semiconductor element; and the magnetization rotational element according to the first aspect or the magnetoresistance effect element according to the second aspect, wherein the magnetization rotational element or the magnetoresistance effect element may be joined to the integrated substrate with the joint layer therebetween.

(13) In the integrated device according to the above aspect, the integrated device may further include: a second joint layer between the integrated substrate and the magnetization rotational element or the magnetoresistance effect element, wherein the joint layer and the second joint layer may contain a same material.

(14) A method of manufacturing an integrated device according to a fourth aspect may include: a step of joining the magnetization rotational element according to the above aspect or the magnetoresistance effect element according to the above aspect above an integrated substrate containing a semiconductor element with the joint layer therebetween.

(15) In the method of manufacturing an integrated device according to the above aspect, the method of manufacturing an integrated device may further include: a step of ion-implanting hydrogen ions into the single crystalline substrate in the magnetization rotational element or the magnetoresistance effect element; and a step of heating the single crystalline substrate after the ion implantation and cutting the single crystalline substrate at a portion at which the hydrogen ions are implanted.

(16) In the method of manufacturing an integrated device according to the above aspect, the ion implantation may be performed before the magnetization rotational element or the magnetoresistance effect element and the integrated substrate are joined.

(17) In the method of manufacturing an integrated device according to the above aspect, the method of manufacturing an integrated device may further include: a step of laminating graphene in a middle of the single crystalline substrate or between the single crystalline substrate and the magnetization stabilizing layer in the magnetization rotational element or the magnetoresistance effect element; and a step of performing cleaving at an interface at which the graphene is laminated and removing the single crystalline substrate.

(18) In the method of manufacturing an integrated device according to the above aspect, at least a magnetization stabilizing layer and a first ferromagnetic metal layer may be epitaxially grown above the single crystalline substrate at a time of laminating the magnetization rotational element or the magnetoresistance effect element.

### Advantageous Effects of Invention

According to the present disclosure, a magnetization rotational element, a magnetoresistance effect element, and an integrated device which have a high magnetic anisotropy even above an integrated substrate and a method of manufacturing the same can be provided.

### BRIEF DESCRIPTION OF DRAWINGS

FIG. 1 is a schematic cross-sectional view of an integrated device according to a first embodiment.

FIG. 2 is a schematic cross-sectional view of a magnetoresistance effect element used for the integrated device according to the first embodiment.

FIG. 3 is a schematic cross-sectional view of another example of the magnetoresistance effect element used for the integrated device according to the first embodiment.

FIG. 4 is a diagram for explaining a method of manufacturing the integrated device according to the first embodiment.

FIG. 5 is a schematic cross-sectional view of an integrated device according to a second embodiment.

FIG. 6 is a schematic cross-sectional view of a magnetization rotational element used for the integrated device according to the second embodiment.

### DESCRIPTION OF EMBODIMENTS

Embodiments of the present disclosure will be described in detail below with reference to the accompanying drawings. It should be noted that, in the description of the drawings, the same constituent elements are denoted with the same reference numerals and overlapping description thereof will be omitted.

### First Embodiment

### “Lamination Element”

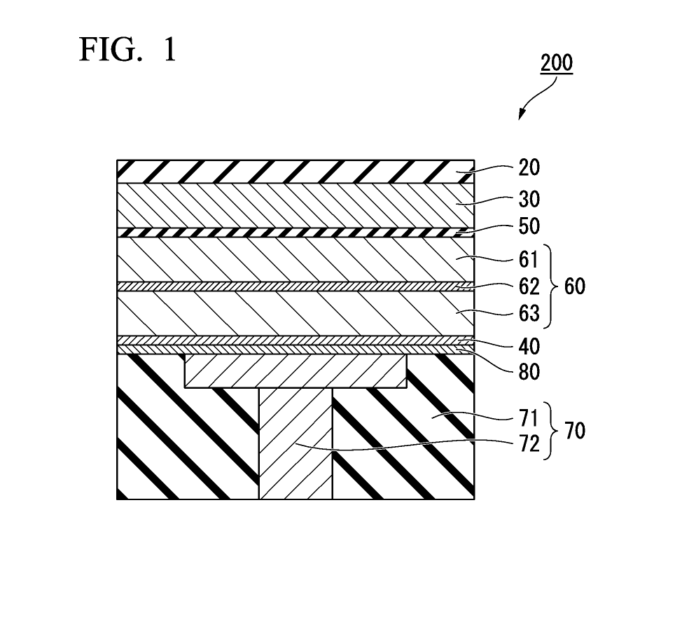

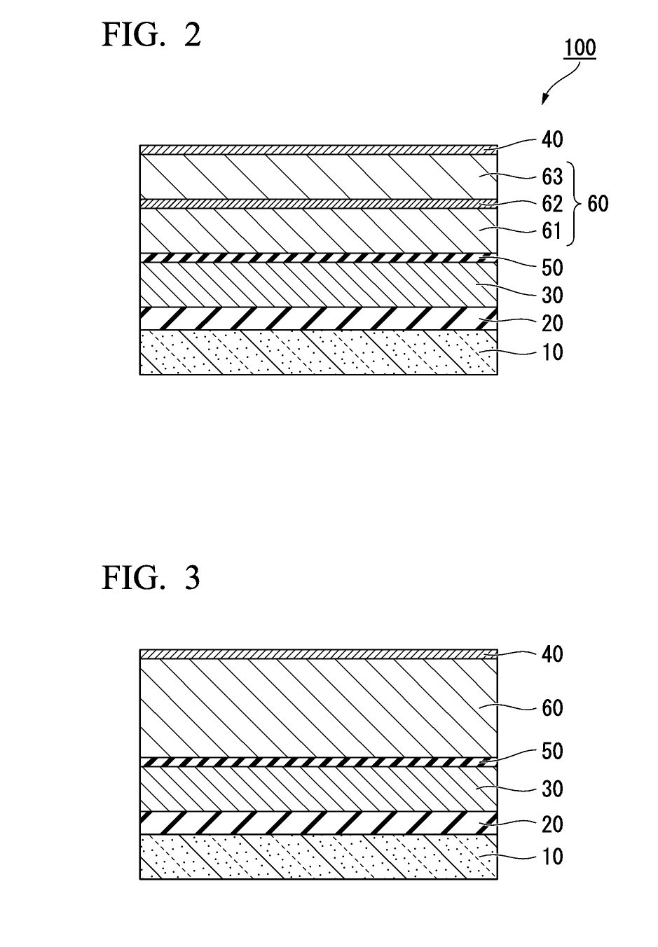

FIG. 1 is a schematic cross-sectional view of a lamination element according to a first embodiment. As illustrated in FIG. 1, the lamination element according to the first embodiment is obtained when an integrated substrate 70 and a magnetoresistance effect element 100 (refer to FIG. 2) are joined with a joint layer 40 therebetween. FIG. 1 shows a state in which a single crystalline substrate 10 of the magnetoresistance effect element 100 (refer to FIG. 2) is removed after the joining. The magnetoresistance effect element 100 illustrated in FIG. 1 includes a second joint layer 80 between the integrated substrate 70 and the magnetoresistance effect element 100.

### “Magnetoresistance Effect Element”

FIG. 2 is a schematic cross-sectional view of a magnetoresistance effect element used for the integrated device according to the first embodiment. The magnetoresistance effect element 100 illustrated in FIG. 2 includes the single crystalline substrate 10, a magnetization stabilizing layer 20, a first ferromagnetic metal layer 30, a nonmagnetic layer 50, a second ferromagnetic metal layer 60, and the joint layer 40. In the magnetoresistance effect element 100, at least the single crystalline substrate 10, the magnetization stabilizing layer 20, and the first ferromagnetic metal layer 30 are single-crystallized.

The word “single-crystallized” means that at least the magnetization stabilizing layer 20 and the first ferromagnetic metal layer 30 are epitaxially grown above the single crystalline substrate 10 and lamination interfaces are connected at an atomic level.

The expression “lamination interfaces are connected at an atomic level” means that all atoms need not be continuously connected in a lamination direction and at least 90% of atoms in a lamination interface are continuous in the lamination direction.

Also, confirmation concerning the expression “lamination interfaces are connected at an atomic level” can be performed on the basis of an image of a scanning transmission electron microscope (STEM). When confirmation is difficult with only an STEM image, an inverse Fourier transform image of a (220) site obtained by performing Fourier transform on information regarding a region near an interface obtained from the STEM image may be checked. In an inverse Fourier transform image, the presence or absence of misfit dislocation can be easily observed because information regarding a lamination direction of atoms is extracted.

When at least the layers in the magnetoresistance effect element 100 are single-crystallized, a magnetoresistance (MR) ratio is enhanced. In the magnetoresistance effect element 100, lamination is generally performed in the order from a substrate. A thickness of each layer in the magnetoresistance effect element 100 is very thin, ranging from several nm to several ten nm and is susceptible to an influence of a base. When a single crystal is used as a substrate and each layer is epitaxially grown above the single crystal, crystallinity of each layer is increased. As a result, magnetic anisotropy of the first ferromagnetic metal layer 30 can be increased and an MR ratio of the magnetoresistance effect element 100 is enhanced.

A technique for flattening a single crystalline substrate has been established. Each layer epitaxially grown above a flattened single crystal has high flatness and the magnetoresistance effect element 100 is a laminated film having high flatness. For example, if laminated layers have a flatness within at least three atomic layers in a structure in which a current path of the magnetoresistance effect element 100 is limited, pressure resistance with respect to an applied voltage is also improved.

In addition, when each layer is epitaxially grown above a single crystal, granular growth can be prevented. As a result, a barrier height of a nonmagnetic layer which effectively decreases at a grain boundary can be kept high. Thus, it is possible to improve pressure resistance of the magnetoresistance effect element 100 as well as a yield of device manufacturing.

A constitution of each layer will be described in detail below.

### (Single Crystalline Substrate)

The single crystalline substrate 10 is a base layer of the magnetoresistance effect element 100 but is a layer which can be removed from an integrated device 200. For this reason, the single crystalline substrate 10 can be selected with a focus on manufacturing the magnetoresistance effect element 100.

In order to enhance an MR ratio of the magnetoresistance effect element 100, it is desirable that the single crystalline substrate 10 be made of a material having high lattice matching with the magnetization stabilizing layer 20 to be laminated. To be specific, the single crystalline substrate 10 is preferably made of at least one selected from the group consisting of Si, GaAs, Ge, MgO, materials with a spinel type structure, and cubic perovskite materials. Examples of materials with a spinel type structure include MgAl₂O₄, ZnAl₂O₄, γ-Al₂O₃, and the like and examples of materials with a cubic perovskite structure include SrTiO₃ and the like.

Here, the expression “high lattice matching” means that a degree of matching between a periodic structure of a crystal on a side on which a layer is laminated and a periodic structure of a crystal on a side to be laminated is high. Hereinafter, a level of the lattice matching is represented by an index referred to as a degree of lattice matching. The degree of lattice matching is an index indicated by |A−B|/A×100 when it is assumed that a periodic structure of a crystal on a side on which a layer is laminated is A and a periodic structure of a crystal on a side to be laminated. Lattice matching is high when the degree of lattice matching is small and lattice matching is small when the degree of lattice matching is high. As the periodic structure A of the crystal on the side on which a layer is laminated and the periodic structure B of the crystal on the side to be laminated, an integer multiple or the like of a lattice constant of each of the crystals can be used.

### (Magnetization Stabilizing Layer)

The magnetization stabilizing layer 20 is a layer laminated above the single crystalline substrate 10. The magnetization stabilizing layer 20 enhances magnetic anisotropy of the first ferromagnetic metal layer 30 at a stage of preparing the magnetoresistance effect element 100 and prevents deterioration of the first ferromagnetic metal layer 30 after the integrated device 200 is completed. It is desirable that a material, a constitution, or the like of the magnetization stabilizing layer 20 be selected in consideration of its function at the stage of preparing the magnetoresistance effect element 100 and its function as the integrated device 200 after adhering. In other words, the magnetization stabilizing layer 20 is preferably made of a material which is easily lattice-matched with the single crystalline substrate 10 and has a high spin/orbit interaction such as an oxide or a heavy metal capable of imparting interfacial magnetic anisotropy to the first ferromagnetic metal layer 30.

In the stage of preparing the magnetoresistance effect element 100, the magnetization stabilizing layer 20 contributes to enhancement of an MR ratio of the magnetoresistance effect element 100. When the magnetization stabilizing layer 20 is epitaxially grown above the single crystalline substrate 10, the crystallinity of the first ferromagnetic metal layer 30 laminated thereon is increased and magnetic anisotropy thereof is increased.

It is desirable that the magnetization stabilizing layer 20 have high lattice matching (small degree of lattice matching) with the single crystalline substrate 10. To be specific, a degree of lattice matching between the single crystalline substrate 10 and the magnetization stabilizing layer 20 is preferably 10% or less, more preferably 6% or less, and further preferably 4% or less. If the degree of lattice matching is 10% or less, 90% or more atoms in an in-plane direction are continuous in the lamination direction and epitaxial grown can be performed.

As such a material, at least one selected from the group consisting of MgO, Ir, and materials with a spinel type structure can be used. Examples of materials with a spinel type structure include the above-described materials.

Also, among these materials, oxides such as MgO, MgAl₂O₄, ZnAl₂O₄, SrTiO₃, and γ-Al₂O₃ are particularly desirable. Oxygen in the magnetization stabilizing layer 20 imparts interfacial magnetic anisotropy at an interface between the first ferromagnetic metal layer 30 and the magnetization stabilizing layer 20 and increases perpendicular magnetic anisotropy of magnetization in the first ferromagnetic metal layer 30.

In order to increase integration of the integrated device 200, a magnetization direction of the first ferromagnetic metal layer 30 preferably has perpendicular magnetic anisotropy which is perpendicular to a lamination surface. A magnetization direction of a magnetic body is greatly affected by a film thickness of a magnetic body and an interface of a laminate. When a layer adjacent to a ferromagnetic body contains oxygen, interfacial magnetic anisotropy is strengthened due to an effect of oxygen. In other words, when the magnetization stabilizing layer 20 contains oxygen, perpendicular magnetic anisotropy of the first ferromagnetic metal layer 30 is increased.

It is desirable that the magnetization stabilizing layer 20 and the single crystalline substrate 10 be made of different materials. When the magnetization stabilizing layer 20 and the single crystalline substrate 10 are made of different materials, lattice matching at an interface of each layer can be adjusted using the magnetization stabilizing layer 20 even when lattice matching between the single crystalline substrate 10 and the first ferromagnetic metal layer 30 is low (degree of lattice matching is large). Furthermore, since the single crystalline substrate 10 can be arbitrarily selected, it is possible to reduce the manufacturing costs and increase the number of choices in the process.

There are minute pits, foreign substances, or the like in interfaces of the single crystalline substrate 10 and the laminated magnetization stabilizing layer 20 even when the magnetization stabilizing layer 20 and the single crystalline substrate 10 are made of the same material and determination concerning these interfaces can be performed based on an image form a transmission electron microscope (TEM) or the like. Examples of foreign substances include oxides of the magnetization stabilizing layer 20 and the single crystalline substrate 10 and compounds thereof.

On the other hand, in the integrated device 200, the magnetization stabilizing layer 20 functions as a cap layer. The cap layer contributes to prevention of oxidation of the integrated device 200, prevention of element diffusion from the integrated device 200, improvement of crystal orientation of the integrated device 200, and the like.

For example, when the first ferromagnetic metal layer 30 is oxidized, a part of the first ferromagnetic metal layer 30 is nonmagnetic and magnetic anisotropy is reduced. When the cap layer is provided, magnetization stability of the first ferromagnetic metal layer 30 is increased.

Also, for example, wirings or the like through which a current flows to the magnetoresistance effect element 100 are integrated above the integrated device 200 in an integrated circuit in some cases. In this case, there is a concern concerning some of elements constituting the first ferromagnetic metal layer 30 diffusing into the integrated wirings. When the elements constituting the first ferromagnetic metal layer 30 diffuse threreinto, the magnetization stability of the first ferromagnetic metal layer 30 is reduced. The magnetization stabilizing layer functioning as the cap layer inhibits element diffusion and increases magnetization stability of the first ferromagnetic metal layer 30.

Ru, Ta, Cu, Ag, Au, or the like can be used for the magnetization stabilizing layer 20 in consideration of only the function as the above-described cap layer. However, these materials do not have excellent lattice matching with the single crystalline substrate 10 and cannot be epitaxially grown. On the other hand, at least one selected from the group consisting of MgO, Ir, and materials with a spinel type structure described above can be epitaxially grown above the single crystalline substrate 10 and appropriately function as a cap layer. It is particularly desirable to select the same material as that of the nonmagnetic layer 50 for the magnetization stabilizing layer 20 in consideration of the functions of a cap layer as well.

A thickness of the magnetization stabilizing layer 20 is preferably 1 nm or more. When the magnetization stabilizing layer 20 has a sufficient film thickness, a difference in degree of lattice matching between the single crystalline substrate 10 and the first ferromagnetic metal layer 30 can be adjusted. Furthermore, when the magnetization stabilizing layer 20 has a sufficient film thickness, its function as a cap layer can be sufficiently achieved. On the other hand, in order to sufficiently secure conductivity between the wirings integrated above the integrated device 200 and the magnetoresistance effect element 100, the thickness of the magnetization stabilizing layer 20 is more preferably 3 nm or less.

### (First Ferromagnetic Metal Layer)

The first ferromagnetic metal layer 30 may be a magnetization fixed layer whose magnetization direction is fixed and a magnetization free layer whose magnetization direction is variable.

In the integrated device 200, magnetization stability is increased when the magnetization fixed layer is present on the integrated substrate 70 side. Furthermore, magnetization stability of a magnetic body on the single crystalline substrate 10 side is then high in the process of manufacturing the magnetoresistance effect element 100. In the case in which a substrate is the single crystalline substrate 10, an MR ratio of the magnetoresistance effect element 100 is enhanced when magnetic characteristics of the magnetization free layer are improved. For this reason, it is desirable that the first ferromagnetic metal layer 30 be a magnetization free layer. Hereinafter, the first ferromagnetic metal layer 30 will be referred to as a magnetization free layer.

As a material of the first ferromagnetic metal layer 30, a ferromagnetic material, particularly, a soft magnetic material may be applied. The first ferromagnetic metal layer 30 is preferably a cubic ferromagnetic metal containing Fe. When the first ferromagnetic metal layer 30 has a cubic crystal structure, lattice matching with the magnetization stabilizing layer 20 is easily increased and epitaxial growth is easily performed.

Examples of the cubic ferromagnetic metal containing Fe include an alloy containing a metal selected from the group consisting of Cr, Mn, Co, Fe, and Ni, an alloy containing at least one metal selected from this group, or one or more metals selected from this group and at least one element of B, C, and N. To be specific, Co—Fe, Co—Fe—B, and Ni—Fe can be exemplified.

Also, the first ferromagnetic metal layer 30 may be made of a Heusler alloy such as Co₂FeSi. A Heusler alloy has high spin polarizability and can realize a high MR ratio. A Heusler alloy contains an intermetallic compound having a chemical composition of X₂YZ. X is a transition metal element or a noble metal element from the Co, Fe, Ni, or Cu group in the periodic table. Y is a transition metal from the Mn, V, Cr, or Ti groups or the element X types. Z is a typical element from Group III or Group V. Co₂FeSi, Co₂Mn₁₋ₐFeₐAl_{b}Si_{1-b} (a and b are integers), and the like may be exemplified.

A thickness of the first ferromagnetic metal layer 30 is preferably 4 nm or less. If the thickness of the first ferromagnetic metal layer 30 is within this range, perpendicular magnetic anisotropy can be imparted to the first ferromagnetic metal layer 30 at each interface with the magnetization stabilizing layer 20 and the nonmagnetic layer 50. Furthermore, since an effect of perpendicular magnetic anisotropy is attenuated due to an increased film thickness of the first ferromagnetic metal layer 30, it is desirable that the film thickness of the first ferromagnetic metal layer 30 be thin. On the other hand, from the viewpoint of obtaining a high MR ratio, it is desirable that the thickness of the first ferromagnetic metal layer 30 be a thickness corresponding to about a spin diffusion length of the first ferromagnetic metal layer 30.

A degree of lattice matching of the first ferromagnetic metal layer 30 to the magnetization stabilizing layer 20 is preferably 6% or less, more preferably 4% or less, and further preferably 2% or less. If the degree of lattice matching is in this range, the first ferromagnetic metal layer 30 can be epitaxially grown above the magnetization stabilizing layer 20. When the first ferromagnetic metal layer 30 is epitaxially grown, the single crystalline substrate 10, the magnetization stabilizing layer 20, and the first ferromagnetic metal layer 30 are single-crystallized.

Examples of materials that satisfy a degree of lattice matching with respect to the magnetization stabilizing layer 20 of 6% or less include Fe, a Fe—Co alloy, Co₂FeSi, Co₂Mn₁₋ₐFeₐAl_{b}Si_{1-b} (a and b are integers), and the like.

### (Nonmagnetic Layer)

A known material can be used for the nonmagnetic layer 50.

For example, when the nonmagnetic layer 50 is made of an insulator (in the case of a tunnel barrier layer), Al₂O₃, SiO₂, MgO, MgAl₂O₄, and the like can be used as a material thereof. Furthermore, in addition to these materials, materials or the like in which a part of Al, Si, and Mg is substituted with Zn, Be, or the like can be used. Among these, spins can be injected efficiently because MgO and MgAl₂O₄ are materials which can realize coherent tunneling.

When the nonmagnetic layer 50 is made of a metal, Cu, Au, Ag, or the like can be used as a material thereof.

It is desirable that the nonmagnetic layer 50 be also single-crystallized together with the single crystalline substrate 10, the magnetization stabilizing layer 20, and the first ferromagnetic metal layer 30. In order to realize the single-crystallization, the nonmagnetic layer 50 preferably has a cubic crystal structure and particularly preferably has a spinel structure or a rock salt type structure.

For example, MgO has a rock salt type structure and MgAl₂O₄, ZnAl₂O₄, SrTiO₃, γ-Al₂O₃, and the like have a spinel structure. The rock salt type structure is a so-called NaCl type structure, in which Mg ions and oxygen ions are alternately arranged. On the other hand, the spinel structure mentioned herein is a concept that includes both a regular spinel structure and a Sukenel structure of a normal spinel and an inverse spinel.

The Sukenel structure is a structure in which two cations constituting a spinel structure are irregularly arranged. In the Sukenel structure, an arrangement of oxygen ions has a close packed cubic lattice that is substantially the same as that of spinel, but positions occupied by cations are random. In a regular spinel structure, predetermined cations are regularly arranged in tetrahedral voids and octahedral voids of oxygen ions. On the other hand, in the Sukenel structure, cations are randomly arranged in tetrahedral voids and octahedral voids, and in the regular spinel structure, different cations are arranged in tetrahedral locations and octahedral locations of oxygen atoms occupied by predetermined cations. As a result, a symmetry of a crystal in the Sukenel structure changes and the Sukenel structure has a structure in which a lattice constant thereof is substantially halved compared with a regular spinel structure.

When the magnetization stabilizing layer 20 is formed of an oxide film, the nonmagnetic layer 50 is preferably made of the same material as the magnetization stabilizing layer 20. Materials which can be used for the magnetization stabilizing layer 20 and the nonmagnetic layer 50 are similar. When the same material as the magnetization stabilizing layer 20 is used for the nonmagnetic layer 50, a degree of lattice matching with the first ferromagnetic metal layer 30 is necessarily increased and an MR ratio of the magnetoresi stance effect element 100 increases.

### (Second Ferromagnetic Metal Layer)

The second ferromagnetic metal layer 60 is a magnetization fixed layer when the first ferromagnetic metal layer 30 is a magnetization free layer and is a magnetization free layer when the first ferromagnetic metal layer 30 is a magnetization fixed layer. Hereinafter, the second ferromagnetic metal layer 60 will be referred to as a magnetization fixed layer.

The same material as the first ferromagnetic metal layer 30 can be used for the second ferromagnetic metal layer 60. It is desirable that the second ferromagnetic metal layer 60 be also single-crystallized together with the single crystalline substrate 10, the magnetization stabilizing layer 20, and the first ferromagnetic metal layer 30.

In order to increase a coercive force of the second ferromagnetic metal layer 60 to higher than that of the first ferromagnetic metal layer 30, the second ferromagnetic metal layer 60 preferably has a synthetic anti-ferromagnetic structure as illustrated in FIGS. 1 and 2.

The synthetic anti-ferromagnetic structure is composed of two magnetic layers 61 and 63 which sandwiches a nonmagnetic layer 62. The magnetization of each of the two magnetic layers 61 and 63 is fixed and the fixed magnetization directions are opposite. For this reason, the magnetization of the two magnetic layers 61 and 63 can be kept stable even when the magnetization of a magnetization free layer (the first ferromagnetic metal layer 30) moves and a coercive force of the second ferromagnetic metal layer 60 can be increased. Furthermore, since magnetic fields occurring due to the two magnetic layers 61 and 63 cancel each other out, an influence of a leakage magnetic field on the first ferromagnetic metal layer 30 can also be minimized.

For example, when the second ferromagnetic metal layer 60 includes FeB (1.0 nm)/Ta(0.2 nm)/[Pt(0.16 nm)/Co(0.16 nm)]₄/Ru(0.9 nm)/[Co(0.24 nm)/Pt(0.16 nm)]₆ formed in the order from the single crystalline substrate 10 side, a magnetization direction thereof can be set to be perpendicular.

Also, as illustrated in FIG. 3, the second ferromagnetic metal layer 60 may have a structure in which a thickness of the second ferromagnetic metal layer 60 is thicker than that of the first ferromagnetic metal layer 30. When the thickness of the second ferromagnetic metal layer 60 is increased, a total amount of magnetization in the second ferromagnetic metal layer 60 is increased and a coercive force thereof is increased.

### (Joint Layer)

The joint layer 40 is laminated above the second ferromagnetic metal layer 60. The joint layer 40 functions as a cap layer at a stage of preparing the magnetoresistance effect element 100 and is used for joining the magnetoresistance effect element 100 and the integrated substrate 70 in the integrated device 200. For this reason, it is desirable that a material, a constitution, or the like of the joint layer 40 be selected in consideration of its function in the state of preparing the magnetoresistance effect element 100 and its function as the integrated device 200 after adhering.

The function of the joint layer 40 as the cap layer is prevention of oxidation of the magnetoresistance effect element 100, improvement of crystal orientation of the magnetoresistance effect element 100, and the like. The cap layer stabilizes the magnetism of the first ferromagnetic metal layer 30 and the second ferromagnetic metal layer 60 in the magnetoresistance effect element 100 and reduces a resistance of the magnetoresistance effect element 100.

The joint layer 40 preferably contains at least one element selected from the group consisting of Ta, Au, In, Cu, Ag, Pt, Pd, Ti, V, and Ru. When pressure is applied to these amorphous materials, the magnetoresistance effect element 100 and the integrated substrate 70 are joined.

These materials also function as a cap layer of the magnetoresistance effect element 100. For this reason, from the viewpoint of a function as a cap layer, it is particularly desirable to include at least one atom selected from the group consisting of Ta, Au, In, and Cu.

### “Integrated Substrate”

An arbitrary substrate including a semiconductor element can be used as the integrated substrate 70. For example, the integrated substrate 70 may include an interlayer insulating layer 71 and a through electrode 72. The through electrode 72 electrically connects a plurality of elements separated by the interlayer insulating layer 71. A semiconductor element or the like (not shown) is connected to the through electrode 72.

The interlayer insulating layer 71 is an insulating layer which insulates between wirings or between elements in a multilayer wiring. A material that is the same as that used in a semiconductor device or the like can be used for the interlayer insulating layer 71. Example of the material include silicon oxides (SiOₓ), silicon nitrides (SiNₓ), silicon carbide (SiC), chromium nitride (CrN), silicon carbonitride (SiCN), silicon oxynitride (SiON), aluminum oxide (Al₂O₃), zirconium oxides (ZrOₓ), or the like.

A known material with high conductivity can be used for the through electrode 72. Examples of the material include any single material selected from the group consisting of Cu, Al, Ti, Nb, V, Ta, and Zr, an alloy thereof, nitrides thereof, and the like.

### (Second Joint Layer)

The second joint layer 80 is disposed between the magnetoresistance effect element 100 and the integrated substrate 70. The second joint layer 80 contains the same material as the joint layer 40. In other words, the second joint layer 80 preferably contains at least one element selected from the group consisting of Ta, Au, In, Cu, Ag, Pt, Pd, Ti, V, and Ru.

The second joint layer 80 increases joining between the magnetoresistance effect element 100 and the integrated substrate 70. When the second joint layer 80 which contains the same material as the joint layer 40 is provided, layers which contain the same material are joined at the time of joining. The same materials are easily joined and have greater adhesion than that of a case in which the second joint layer 80 is not provided.

Even at a stage of the integrated device 200 after the magnetoresistance effect element 100 and the integrated substrate 70 are joined, determination concerning an interface between the joint layer 40 and the second joint layer 80 can be performed using a TEM or the like.

“Method of Manufacturing Integrated Device”

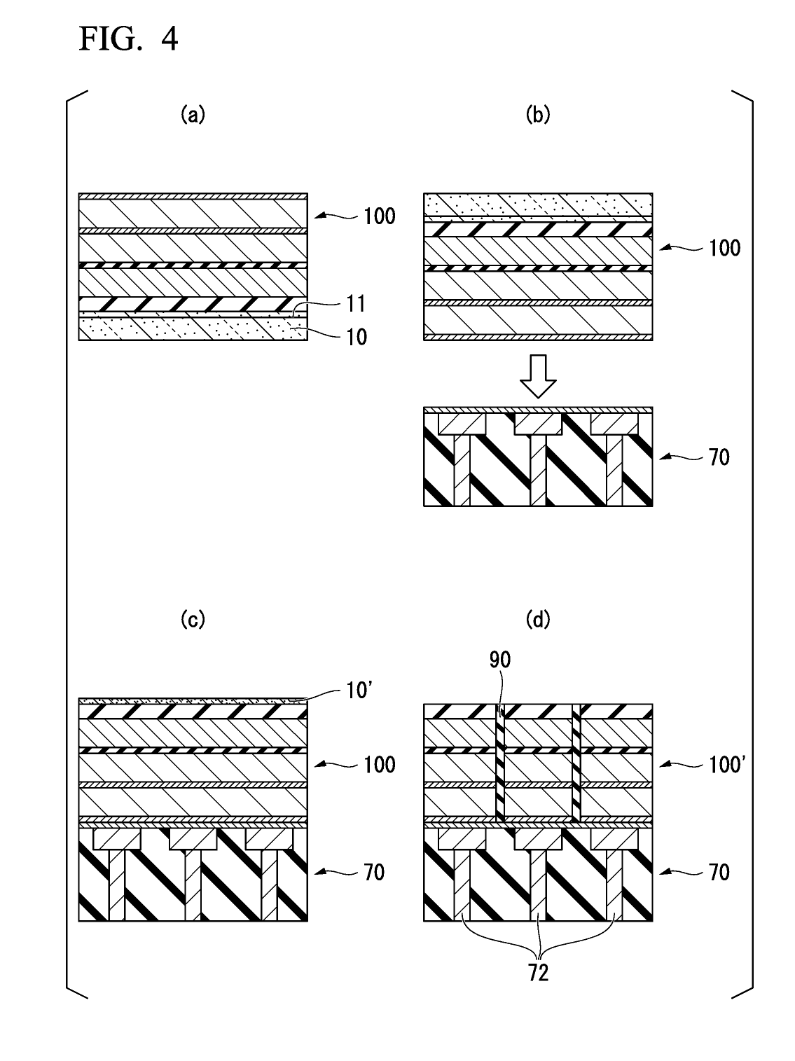

A method of manufacturing the integrated device 200 will be described below with reference to FIG. 4. FIG. 4 is a diagram for explaining a method of manufacturing the integrated device according to the first embodiment.

First, as illustrated in (a) of FIG. 4, the magnetoresistance effect element 100 is prepared. The magnetoresistance effect element 100 can be prepared using a known film formation method. Examples of the film formation method include a normal thin film preparation method such as a sputtering method, a vapor deposition method, a laser ablation method, and a molecular beam epitaxy (MBE) method.

When lamination is performed in the magnetoresistance effect element 100, growth conditions are adjusted so that at least the single crystalline substrate 10, the magnetization stabilizing layer 20, and the first ferromagnetic metal layer 30 are epitaxially grown. For example, a degree of film formation vacuum is increased, a distance between a target and an object subjected to film formation is increased, and an applied voltage is decreased.

When film formation conditions are set to be gentle in this way, epitaxial growth is performed according to respective crystal structures.

When the nonmagnetic layer 50 is a tunnel barrier layer, an oxide film can be formed by sputtering a metal thin film and performing plasma oxidation or natural oxidation through oxygen introduction and heat treatment on the metal thin film.

Although details will be described later, in the integrated device 200, the single crystalline substrate 10 is removed. For this reason, in order to easily remove the single crystalline substrate 10, hydrogen ions may be ion-implanted into the single crystalline substrate 10. Hydrogen ions implanted into the single crystalline substrate 10 with the same energy are arranged at the same position in the single crystalline substrate 10. Hereinafter, a portion into which hydrogen ions are implanted is referred to as an ion implantation portion 11.

The ion implantation portion 11 is preferably provided at a position which is 100 nm or less away from a lamination surface of the single crystalline substrate 10. The single crystalline substrate 10 is divided by the ion implantation portion 11. Thus, when the ion implantation portion 11 is provided at this position, a process of removing the single crystalline substrate 10 which will be described later can be simplified.

Ion implantation is preferably performed before the magnetoresistance effect element 100 and the integrated substrate 70 are joined. In other words, ion implantation is preferably performed at a stage of the single crystalline substrate 10 before the magnetoresistance effect element 100 is laminated or at a stage of the magnetoresistance effect element 100 after the magnetoresistance effect element 100 is laminated.

Ion implantation can be performed from any side of the single crystalline substrate 10 and can be easily performed as long as the magnetoresistance effect element 100 has not been laminated. Furthermore, when the magnetoresistance effect element 100 has not been laminated, workability is excellent.

On the other hand, when ion implantation is performed after the magnetoresistance effect element 100 is laminated, an influence of ion-implanted hydrogen ions when a magnetic film such as the first ferromagnetic metal layer 30 is laminated is prevented.

Subsequently, as illustrated in (b) of FIG. 4, the magnetoresistance effect element 100 and the integrated substrate 70 are joined with the joint layer 40 therebetween. It is desirable to form the second joint layer 80 on a joint surface of the integrated substrate 70.

The joining is performed by applying pressure in a lamination direction after the magnetoresistance effect element 100 and the integrated substrate 70 are laminated. When pressure is applied, the amorphous joint layer 40 functions like an adhesive and joins the magnetoresistance effect element 100 and the integrated substrate 70.

It is desirable that a joint surface of the magnetoresistance effect element 100 and the joint surface of the integrated substrate 70 be planarized through chemical mechanical polishing (CMP) before the joining and foreign substances on their surfaces be removed. It is desirable that a flatness of the joint surfaces of the magnetoresistance effect element 100 and the integrated substrate 70 be a height difference of 3 nm within a range of 1000 nm. It is further desirable that the flatness of the joint surfaces of the magnetoresistance effect element 100 and the integrated substrate 70 be a height difference of 1.5 nm within a range of 100 nm.

A pressure applied at the time of joining is preferably 2 GPa or more and more preferably 3 GPa or more. When a sufficient pressure is applied, the magnetoresistance effect element 100 and the integrated substrate 70 are firmly joined. In order to prevent breakage of the magnetoresistance effect element 100 and the integrated substrate 70, an applied voltage is preferably 10 GPa or less.

Subsequently, when ion implantation has been performed, a laminate of the magnetoresistance effect element 100 and the integrated substrate 70 is heated at a temperature of about 400° C. to 1000° C. When the laminate is heated, as illustrated in (c) of FIG. 4, the single crystalline substrate 10 is cleaved at the ion implantation portion 11. A single crystalline substrate 10′ after the cleavage is thinner than the original single crystalline substrate 10 and has a thickness same as a position in which the ion implantation portion 11 is provided.

Moreover, the single crystalline substrate 10′ is removed. Since the single crystalline substrate 10′ is thin, the single crystalline substrate 10′ can be easily removed. Examples of a method for removing the single crystalline substrate 10′ include etching, polishing, reactive ions etching (RIE), and the like.

Although a case in which the ion implantation portion 11 is provided has been described above, the ion implantation portion 11 may not be provided. In this case, the single crystalline substrate 10 is removed through etching or the like. However, it is desirable to cleave the single crystalline substrate 10 using ion implantation and heat treatment in consideration of production efficiency, and damage to a magnetic film.

The single crystalline substrate 10 may be removed by a method other than the above-described method using hydrogen ions. For example, graphene may be provided in the middle of the single crystalline substrate 10 or an interface between the single crystalline substrate 10 and the magnetization stabilizing layer 20. Graphene is a sheet-like material having a thickness corresponding to one atomic layer in which carbon atoms are connected through sp bonds in an in-plane direction and has excellent cleavability. When the single crystalline substrate 10 is cleaved at an interface at which graphene is laminated, the single crystalline substrate 10 can be easily removed.

A thickness of graphene corresponds to one atomic layer and is very thin. For this reason, wave functions of atoms sandwiching graphene in a lamination direction affects atoms located on an opposite side across the graphene. In other words, the presence of graphene does not affect crystallinity in the lamination direction. For this reason, for example, both sides sandwiching graphene coincide in crystallinity of the single crystalline substrate 10 even when graphene is disposed in the middle of the single crystalline substrate 10. Furthermore, for example, a magnetization stabilizing layer 20 may be epitaxially grown above the single crystalline substrate 10 even when graphene is disposed in an interface between the single crystalline substrate 10 and the magnetization stabilizing layer 20.

Finally, as illustrated in (d) of FIG. 4, the magnetoresistance effect element 100 is divided for each semiconductor element provided on the integrated substrate 70. For example, as illustrated in (d) of FIG. 4, the magnetoresistance effect element 100 is divided into a plurality of magnetoresistance effect elements 100′ for each through electrode 72. It is desirable to fill a space between the separate magnetoresistance effect elements 100′ with an insulator 90. A known technique such as photolithography can be used for division between elements of the magnetoresistance effect element 100.

When the above-described manufacturing method is used, the magnetoresistance effect element 100′ can be prepared for each semiconductor element provided on the integrated substrate 70. Furthermore, since the magnetoresistance effect element 100′ formed above each semiconductor element is epitaxially grown above the single crystalline substrate 10, the magnetoresistance effect element 100′ can realize a high MR ratio. A joining process does not adversely affect the magnetization characteristics of the first ferromagnetic metal layer 30 and the second ferromagnetic metal layer 60 constituting the magnetoresistance effect element 100.

In other words, according to the integrated device 200 in this embodiment, the magnetoresistance effect element 100 exhibiting a high MR ratio even above the integrated substrate 70 can be realized.

### Second Embodiment

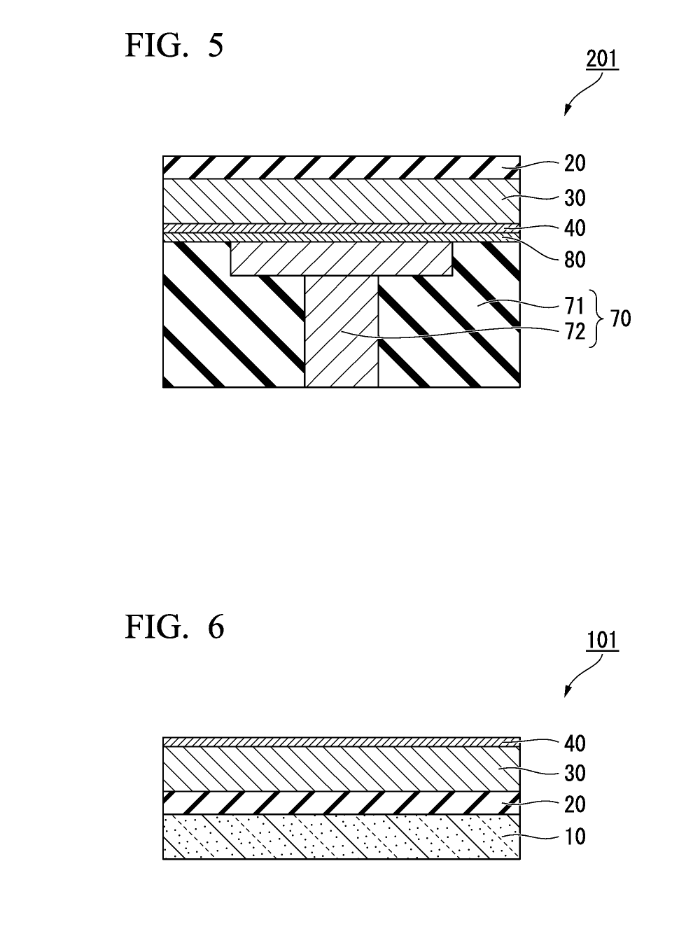

FIG. 5 is a schematic cross-sectional view of an integrated device 201 according to a second embodiment. The integrated device 201 according to the second embodiment and the integrated device 200 according to the first embodiment differ in that the integrated device 201 according to the second embodiment does not include a nonmagnetic layer 50 and a second ferromagnetic metal layer 60. Other constitutions are the same as those of the integrated device 200 according to the first embodiment and description of the same constitution will be omitted.

In the integrated device 201 according to the second embodiment, a magnetization rotational element 101 and an integrated substrate 70 are laminated with a joint layer 40 therebetween. FIG. 6 is a schematic cross-sectional view of a magnetoresistance effect element used for the integrated device according to the second embodiment.

The magnetization rotational element 101 includes a single crystalline substrate 10, a magnetization stabilizing layer 20, a first ferromagnetic metal layer 30, and the joint layer 40 in this order. In the magnetization rotational element 101, at least the single crystalline substrate 10, the magnetization stabilizing layer 20, and the first ferromagnetic metal layer 30 are single-crystallized.

When at least these layers of the magnetization rotational element 101 are single-crystallized, the magnetic anisotropy of the first ferromagnetic metal layer 30 is increased. When the magnetic anisotropy of the first ferromagnetic metal layer 30 is increased, a magnetic Kerr effect, a Faraday effect, or the like can be increased and a deflection element, a magneto-optical recording element, and the like with better performance can be obtained. The magnetization rotational element 101 and the magnetoresistance effect element 100 differ in that the magnetization rotational element 101 does not include the nonmagnetic layer 50 and the second ferromagnetic metal layer 60.

A method of manufacturing the integrated device 201 according to the second embodiment and the method of manufacturing the integrated device 200 according to the first embodiment differ in that only the step of laminating the nonmagnetic layer 50 and the second ferromagnetic metal layer 60 is removed from the step of laminating the magnetoresistance effect element 100 in the method of manufacturing the integrated device 201 according to the second embodiment.

In other words, according to the integrated device 201 in this embodiment, the magnetization rotational element 101 with a high magnetic anisotropy even above the integrated substrate 70 can be realized.

### EXAMPLES

### <Preferred Combination of Materials for Single-Crystallization>

In both of the magnetoresistance effect element 100 according to the first embodiment and the magnetization rotational element 101 according to the second embodiment, at least the single crystalline substrate 10, the magnetization stabilizing layer 20, and the first ferromagnetic metal layer 30 were single-crystallized. Thus, a preferred combination of materials for single-crystallization of these layers was calculated from lattice constants of its crystal structure.

First, a degree of lattice matching of each layer when the single crystalline substrate 10 is made of Si was acquired. The results are represented in Table 1.

TABLE 1

| | | | | | Degree of lattice matching | | |
|---|---|---|---|---|---|---|---|
| | | | | | Interface | Interface | |
| | | | | | between | between | Interface |
| | | | | | single | magnetization | between |
| | Material type | | | | crystalline | stabilizing | first |
| | | Magneti- | | | substrate and | layer and | ferromagnetic |
| | Single | zation | First | Non- | magnetization | first | metal layer |
| | crystalline | stabilizing | ferromagnetic | magnetic | stabilizing | ferromagnetic | and non- |
| | substrate | layer | metal layer | layer | layer | metal layer | magnetic layer |
| Example 1 | Si | MgO | Fe | MgO | 9.70 | 3.75 | 3.90 |
| Example 2 | Si | MgAl₂O | Fe | MgO | 5.26 | 0.31 | 3.90 |
| Example 3 | Si | MgO | Fe | MgAl₂O | 9.70 | 3.75 | 0.30 |
| Example 4 | Si | MgAl₂O | Fe | MgAl₂O | 5.26 | 0.31 | 0.30 |
| Example 5 | Si | Ir | Fe | MgO | 0.01 | 5.59 | 3.90 |
| Example 6 | Si | γ-Al₂O₃ | Fe | MgO | 3.00 | 2.50 | 3.90 |
| Example 7 | Si | γ-Al₂O₃ | Fe | MgAl₂O | 3.00 | 2.50 | 0.30 |
| Example 8 | Si | SrTiO₃ | Fe | MgO | 1.70 | 3.81 | 3.90 |
| Example 9 | Si | MgO | Co₂Cr_{0.3}Fe_{0.7}Si | MgO | 9.70 | 5.32 | 5.61 |
| Example 10 | Si | MgAl₂O | Co₂Cr_{0.3}Fe_{0.7}Si | MgO | 5.26 | 1.32 | 5.61 |
| Example 11 | Si | MgO | Co₂Cr_{0.3}Fe_{0.7}Si | MgAl₂O | 9.70 | 5.32 | 1.40 |
| Example 12 | Si | MgAl₂O | Co₂Cr_{0.3}Fe_{0.7}Si | MgAl₂O | 5.26 | 1.32 | 1.40 |
| Example 13 | Si | Ir | Co₂Cr_{0.3}Fe_{0.7}Si | MgO | 0.01 | 3.87 | 5.61 |
| Example 14 | Si | γ-Al₂O₃ | Co₂Cr_{0.3}Fe_{0.7}Si | MgO | 3.00 | 0.84 | 5.61 |
| Example 15 | Si | γ-Al₂O₃ | Co₂Cr_{0.3}Fe_{0.7}Si | MgAl₂O | 3.00 | 0.84 | 1.40 |
| Example 16 | Si | SrTiO₃ | Co₂Cr_{0.3}Fe_{0.7}Si | MgO | 1.70 | 2.12 | 5.61 |

Next, a degree of lattice matching of each layer when the single crystalline substrate 10 is made of MgO or MgAl₂O was acquired. The results are represented in Table 2.

TABLE 2

| | | | | | Degree of lattice matching | | |
|---|---|---|---|---|---|---|---|
| | | | | | | Interface | Interface |
| | | | | | Interface | between | between |
| | | | | | between | magneti- | first |
| | Material type | | | | single | zation | ferro- |
| | | | First | | crystalline | stabilizing | magnetic |
| | | Magneti- | ferro- | | substrate and | layer and | metal layer |
| | Single | zation | magnetic | Non- | magnetization | first | and |
| | crystalline | stabilizing | metal | magnetic | stabilizing | ferromagnetic | nonmagnetic |
| | substrate | layer | layer | layer | layer | metal layer | layer |
| Example 17 | MgO | MgAl₂O | Fe | MgO | 4.05 | 3.75 | 3.90 |
| Example 18 | MgO | Ir | Fe | MgO | 8.85 | 5.59 | 3.90 |
| Example 19 | MgO | γ-Al₂O₃ | Fe | MgO | 6.10 | 2.50 | 3.90 |
| Example 20 | MgO | SrTiO₃ | Fe | MgO | 7.29 | 3.81 | 3.90 |
| Example 21 | MgAl₂O | MgO | Fe | MgO | 4.22 | 3.75 | 3.90 |
| Example 22 | MgAl₂O | Ir | Fe | MgO | 5.00 | 5.59 | 3.90 |
| Example 23 | MgAl₂O | γ-Al₂O₃ | Fe | MgO | 2.14 | 2.50 | 3.90 |
| Example 24 | MgAl₂O | SrTiO₃ | Fe | MgO | 3.38 | 3.81 | 3.90 |

Next, a degree of lattice matching of each layer when the single crystalline substrate 10 was made of Ge or GaAs was acquired. The results are represented in Table 3.

TABLE 3

| | | | | | Degree of lattice matching | | |
|---|---|---|---|---|---|---|---|
| | | | | | Interface | Interface | Interface |
| | | | | | between | between | between |
| | Material type | | | | single | magnetization | first |
| | | | First | | crystalline | stabilizing | ferro- |
| | | Magneti- | ferro- | | substrate and | layer and | magnetic |
| | Single | zation | magnetic | Non- | magnetization | first ferro- | metal layer |
| | crystalline | stabilizing | metal | magnetic | stabilizing | magnetic | and non- |
| | substrate | layer | layer | layer | layer | metal layer | magnetic layer |
| Example 25 | Ge | MgO | Fe | MgO | 4.96 | 3.75 | 3.90 |
| Example 26 | Ge | Ir | Fe | MgO | 4.33 | 5.59 | 3.90 |
| Example 27 | Ge | γ-Al₂O₃ | Fe | MgO | 1.45 | 2.50 | 3.90 |
| Example 28 | Ge | SrTiO₃ | Fe | MgO | 2.70 | 3.81 | 3.90 |
| Example 29 | GaAs | MgO | Fe | MgO | 5.37 | 3.75 | 3.90 |
| Example 30 | GaAs | Ir | Fe | MgO | 3.95 | 5.59 | 3.90 |
| Example 31 | GaAs | γ-Al₂O₃ | Fe | MgO | 1.06 | 2.50 | 3.90 |
| Example 32 | GaAs | SrTiO₃ | Fe | MgO | 2.31 | 3.81 | 3.90 |

In any combination, the degree of crystal matching between the single crystalline substrate and the magnetization stabilizing layer was 10% or less and the degree of crystal matching between the magnetization stabilizing layer and the first ferromagnetic metal layer was 6% or less. In other words, in at least these combinations, the single crystalline substrate 10, the magnetization stabilizing layer 20, and the first ferromagnetic metal layer 30 were single-crystallized.

### REFERENCE SIGNS LIST

10, 10′: Single crystalline substrate

11: Ion implantation portion

20: Magnetization stabilizing layer

30: First ferromagnetic metal layer

40: Joint layer

50: Nonmagnetic layer

60: Second ferromagnetic metal layer

61, 63: Magnetic layer

62: Nonmagnetic layer

70: Integrated substrate

71: Interlayer insulating layer

72: Through electrode

80: Second joint layer

90: Insulator

100, 100′: Magnetoresistance effect element

101: Magnetization rotational element

200, 201: Integrated device

1. A magnetization rotational element, comprising:
a single crystalline substrate; a magnetization stabilizing layer; a first ferromagnetic metal layer; and a joint layer in an order,
wherein at least the single crystalline substrate, the magnetization stabilizing layer, and the first ferromagnetic metal layer are single-crystallized as a whole.

2. The magnetization rotational element according to claim 1, wherein the single crystalline substrate and the magnetization stabilizing layer contain different materials.

3. The magnetization rotational element according to claim 1, wherein the single crystalline substrate is made of at least one selected from a group consisting of Si, GaAs, Ge, MgO, a material with a spinel type structure, and a material with a cubic perovskite structure.

4. The magnetization rotational element according to claim 1, wherein the magnetization stabilizing layer is made of at least one selected from a group consisting of MgO, Ir, and a material with a spinel type structure.

5. The magnetization rotational element according to claim 1, wherein the first ferromagnetic metal layer is made of a cubic ferromagnetic metal containing Fe.

6. The magnetization rotational element according to claim 1, wherein a degree of lattice matching between the single crystalline substrate and the magnetization stabilizing layer is 10% or less.

7. The magnetization rotational element according to claim 1, wherein a degree of lattice matching between the magnetization stabilizing layer and the first ferromagnetic metal layer is 6% or less.

8. The magnetization rotational element according to claim 1, wherein a thickness of the magnetization stabilizing layer is 1 nm or more.

9. The magnetization rotational element according to claim 1, wherein the joint layer contains at least one element selected from a group consisting of Ta, Au, In, Cu, Ag, Pt, Pd, Ti, V, and Ru.

10. A magnetoresistance effect element, comprising:
between the first ferromagnetic metal layer and the joint layer of the magnetization rotational element according to claim 1,
a nonmagnetic layer and a second ferromagnetic metal layer in an order from the first ferromagnetic metal layer side.

11. The magnetoresistance effect element according to claim 10, wherein the second ferromagnetic metal layer has a synthetic anti-ferromagnetic structure.

12. An integrated device, comprising:
an integrated substrate containing a semiconductor element; and
the magnetization rotational element according to claim 1,
wherein the magnetization rotational element or the magnetoresistance effect element is joined to the integrated substrate with the joint layer therebetween.

13. The integrated device according to claim 12, further comprising:
a second joint layer between the integrated substrate and the magnetization rotational element or the magnetoresistance effect element,
wherein the joint layer and the second joint layer contain a same material.

14. A method of manufacturing an integrated device, comprising:
a step of joining the magnetization rotational element according to claim 1 above an integrated substrate containing a semiconductor element with the joint layer therebetween.

15. The method of manufacturing an integrated device according to claim 14, further comprising:
a step of ion-implanting hydrogen ions into the single crystalline substrate in the magnetization rotational element or the magnetoresistance effect element; and
a step of heating the single crystalline substrate after the ion implantation and cutting the single crystalline substrate at a portion at which the hydrogen ions are implanted.

16. The method of manufacturing an integrated device according to claim 15, wherein the ion implantation is performed before the magnetization rotational element and the integrated substrate are joined.

17. The method of manufacturing an integrated device according to claim 14, further comprising:
a step of laminating graphene in a middle of the single crystalline substrate or between the single crystalline substrate and the magnetization stabilizing layer in the magnetization rotational element or the magnetoresistance effect element; and
a step of performing cleaving at an interface at which the graphene is laminated and removing the single crystalline substrate.

18. The method of manufacturing an integrated device according to claim 14, wherein at least a magnetization stabilizing layer and a first ferromagnetic metal layer are epitaxially grown above the single crystalline substrate at a time of laminating the magnetization rotational element or the magnetoresistance effect element.

19. The magnetization rotational element according to claim 2, wherein the single crystalline substrate is made of at least one selected from a group consisting of Si, GaAs, Ge, MgO, a material with a spinel type structure, and a material with a cubic perovskite structure.

20. The magnetization rotational element according to claim 2, wherein the magnetization stabilizing layer is made of at least one selected from a group consisting of MgO, Ir, and a material with a spinel type structure.
